(19) United States
(12) Patent Application Publication
(10) Pub. No.: US 2012/0012244 A1
(43) Pub. Date: Jan. 19, 2012

(54) TEMPORARY SUBSTRATE, TRANSFER METHOD AND PRODUCTION METHOD

(76) Inventor: Gregory Riou, Crolles (FR)

(21) Appl. No.: 12/897,409

(22) Filed: Oct. 4, 2010

(30) Foreign Application Priority Data
Jul. 15, 2010 (FR) FR 1 055 767

(51) Int. Cl. B32B 38/10; B32B 15/20; B32B 3/18; B32B 37/30; C23C 16/56

(52) U.S. Cl. 156/230; 156/60; 216/37; 428/189; 428/47

(57) ABSTRACT

The present invention relates to a method of manufacturing a temporary substrate, the temporary substrate thus produced, and a method of using the temporary substrate for transfer of a thin layer from an original substrate to a final substrate. The temporary substrate has a principle part of the original substrate and a surface layer thereon that includes a plurality of inserts formed of a material having a coefficient of thermal expansion different from that of the material constituting the rest of the surface layer. When exposed to heat treatment, these inserts form detachment zones between the upper face of an attached thin layer and the temporary substrate.

### FIELD OF THE INVENTION

The present invention relates to the field of temporary substrates used in the semiconductor industry for the transfer of a thin layer from a source or original substrate to a receiving or final substrate.

### BACKGROUND OF THE INVENTION

Semiconducting structures serve as the basis for the electronics industry. In order to improve performance, methods have been developed for increasing more and more the density of etched circuits per unit area. However, a physical limit is eventually approached. It is for this reason that three-dimensional integration methods have appeared. Instead of always reducing the size of circuits, it is sufficient to stack them in 3-D structures and to connect them by vertical interconnections.

The production of these types of structure requires the successive transfer of layers from which they are made. These layers are typically produced separately on specific substrates called “original substrates” of a particular materials. It is then necessary to use a temporary substrate also called a “sacrificial substrate,” in order to transfer them onto their final substrate in a manner that the surface of the layer is facing in the right direction.

The steps of an example of such a transfer are shown in FIG. 1. The temporary substrate 100 is attached to the topside of the layer 4 to be transferred, and the original substrate 5 on which the layer 4 was attached is then removed. The layer 4 is attached to the final substrate 8, covered as the case may be with one or more other layers 7 in the case of a 3-D structure. Finally, the temporary substrate 100 is demounted.

In point of fact, adhesion between the temporary substrate and attached layer should be sufficient, so that there is no risk of premature detachment of part of the layer to be transferred.

One difficulty lies in the final detachment or demounting of the temporary substrate. A first technique called “laser lift off” requires the use of a transparent substrate and an adhesive material that is sensitive to laser excitation. Another technique, described in U.S. Patent Application Publication US 2004/222500 to Aspar et al. published Nov. 11, 2004, proposes the use of a rough temporary support that may be detached by a final mechanical action.

Each of these solutions provide satisfactory results but the overall process remains very slow. The larger the substrate, the longer the detachment time. Although for 100 mm diameter substrates, the detachment time may be acceptable, this detachment time proves to be much too long for profitable industrial use for new substrates having a diameter of 300 mm or more. Thus, improvements in such manufacturing processes are necessary.

### SUMMARY OF THE INVENTION

The present invention relates to a method of manufacturing a temporary substrate, the temporary substrate thus produced, and a method of using the temporary substrate for transfer of a thin layer from an original substrate to a final substrate, characterized in that the temporary substrate has a principle part of a substrate, and a surface layer thereon, having a plurality of inserts formed of a material having a coefficient of thermal expansion different from that of the material constituting the rest of the surface layer, such that detachment zones are formed between the upper face of an attached thin layer and the temporary substrate upon heat treating.

A first aspect of the present invention relates to a temporary substrate used for the transfer of a thin layer of an original substrate to a final substrate comprises a principle part of a substrate; a surface layer formed on the surface of the principle part; and a plurality of separate inserts formed within the surface layer, wherein the inserts have a coefficient of thermal expansion different from that of the surface layer. The principle part of the temporary substrate is chosen from at least one of the following materials: Si, SiC, SiGe, glass, a ceramic, a metal alloy. The surface layer is from a material chosen from at least one of the following materials: tetraethoxysilane or silane, and the inserts can be copper. The inserts can be distributed in the surface layer in a regular pattern, where the regular pattern that the inserts are distributed in can be a checkered pattern. The inserts can be separated two by two by a distance equivalent to their width. The width of the inserts, their spacing or both can be a distance of between 250 and 500 μm.

The thickness of the surface layer of the temporary substrate can be equal to or less than 1 μm, and the inserts can be covered by a thickness of material of the surface layer less than 5000 Å.

The inserts can be placed within cavities in the surface layer, and then covered by subsequently applied additional amounts of surface layer.

A second aspect of the present invention relates to a method for transferring a thin layer of an original substrate to a final substrate using a temporary substrate comprising providing a temporary substrate, as described above; providing an original substrate having a thin layer; attaching the upper face of the thin layer of the original substrate to the temporary substrate; and heat treating the original substrate, thin layer and temporary substrate to bring about the formation of detachment zones between the upper face of the thin layer and the temporary substrate. The method can further comprise eliminating the original substrate to reveal a lower face of the thin layer; attaching the lower face of the thin layer to the final substrate; and detaching by mechanical action the zones of the surface of the temporary substrate that are still attached to the upper face of the thin layer.

A third aspect of the present invention relates to a method for producing a temporary substrate, as described above, comprising providing a substrate having a principle part at a surface; depositing an initial surface layer, such as TEOS or silane, on the principal part of the substrate; etching the surface layer to form a plurality of separate cavities therein; depositing a layer of a material on the surface layer so as to fill the plurality of separate cavities; polishing the layer of the material deposited on the surface layer until the initial surface layer is revealed to form a plurality of separate inserts, wherein the polishing can be a mechano-chemical polishing; and depositing a thin layer of material forming the surface layer on the revealed surface layer and filled cavities, so as to cover the inserts. The material of the surface layer can be deposited by plasma-enhanced chemical vapor deposition (PECVD). The material deposited on the surface layer to fill the cavities is preferably copper. The thin layer of material deposited to cover the inserts can be polished to flatten the deposited surface.

### BRIEF DESCRIPTION OF THE DRAWINGS

Other features and advantages describing the best mode of the present invention will become apparent on reading the following descriptions of the preferred embodiments. These description will be given with reference to the appended drawings in which:

FIG. 1 shows the steps of a known use of a temporary substrate for a layer transfer;

FIG. 2 shows a cross section of an embodiment of a temporary substrate according to a first aspect of the invention;

FIGS. 3 to 6 show cross sections of combinations of various substrates during successive steps of an embodiment of a transfer method according to the second aspect of the invention;

FIG. 7 shows a sagittal section at the level of an interface between a temporary substrate according to an embodiment of the first aspect of the invention and a layer to be transferred;

FIGS. 8 to 15 show cross sections of the temporary substrate during successive steps of an embodiment of its production process according to the third aspect of the invention.

### DETAILED DESCRIPTION OF THE INVENTION

The present invention relates to a temporary substrate for the transfer of a thin layer of an original substrate to a final substrate, characterized in that it comprises a surface layer having a plurality of inserts consisting of material having a coefficient of thermal expansion different from that of the material constituting the rest of the surface layer.

These features of the present invention provide a temporary substrate that facilitates the final detachment of a transferred layer, while eliminating the risk of premature detachment. This temporary substrate makes it possible to gain time by shortening the time necessary for detachment of a transferred layer.

The presence of the inserts with a different coefficient of thermal expansion from the rest of the layer means that, by heating the structure before detachment, cavities appear at the interface between the temporary substrate and the thin layer being transferred. The formation of these cavities causes the area of attachment to be reduced, which brings about a considerable reduction in adhesion and easier detachment.

This variability of adhesion between an initial state of total attachment and a final state of partial attachment means that it is not necessary to limit the initial attachment, and thus to risk premature detachment, in order to have easy final detachment.

According to other advantageous non-limiting features:

the surface layer covers the principal part of the temporary substrate, the principal part consisting of a material chosen from at least one of the following materials:
Si, SiC, SiGe, glass, a ceramic, or a metal alloy;
the surface layer consists of a material chosen from at least one of the following materials: tetraethoxysilane or another silane;
the inserts are preferably copper;
the inserts are distributed in the surface layer in a regular pattern;
the inserts are distributed in a chequered (checkered) pattern;
the inserts are separated two by two by a distance equivalent to their width;
the width of the inserts and/or their spacing lies between 250 and 500 μm;
the inserts are covered by a thickness of the material of the surface layer less than 5000 Å.

According to a second feature, the invention relates to a method for transferring a thin layer of an original substrate to a final substrate via a temporary substrate according to the first feature of the invention, comprising steps of:
attachment of the upper face of the thin layer to the temporary substrate:
heat treatment bringing about the formation of detachment zones between the upper face of the thin layer and the temporary substrate;
elimination of the original substrate;
attachment of the lower face of the thin layer to the final substrate;
detachment, by mechanical action, of the zones of the surface of the temporary substrate that are still attached to the upper face of the thin layer.

According to a third feature, the invention relates to a method for producing a temporary substrate according to the first feature of the invention, comprising steps of:
depositing the surface layer on a principal part;
etching the surface layer to form cavities thereon;
depositing a layer of the material constituting the inserts so as to fill the cavities;
mechano-chemical polishing of the layer of the material of the layer of material constituting the inserts until the material of the surface layer is revealed;
depositing a thin layer of the material of the surface layer so as to cover the inserts.

According to other advantageous non-limiting features, the material of the surface layer is deposited by plasma enhanced chemical vapor deposition.

The present invention shall be further described with reference to the particular embodiments depicted in the drawings. It is understood that these drawings only illustrate some of the preferred embodiments, and do not represent the full scope of the invention for which reference should be made to the accompanying claims.

FIG. 1, discussed above, describes the general process for the transfer of a layer using a temporary substrate.

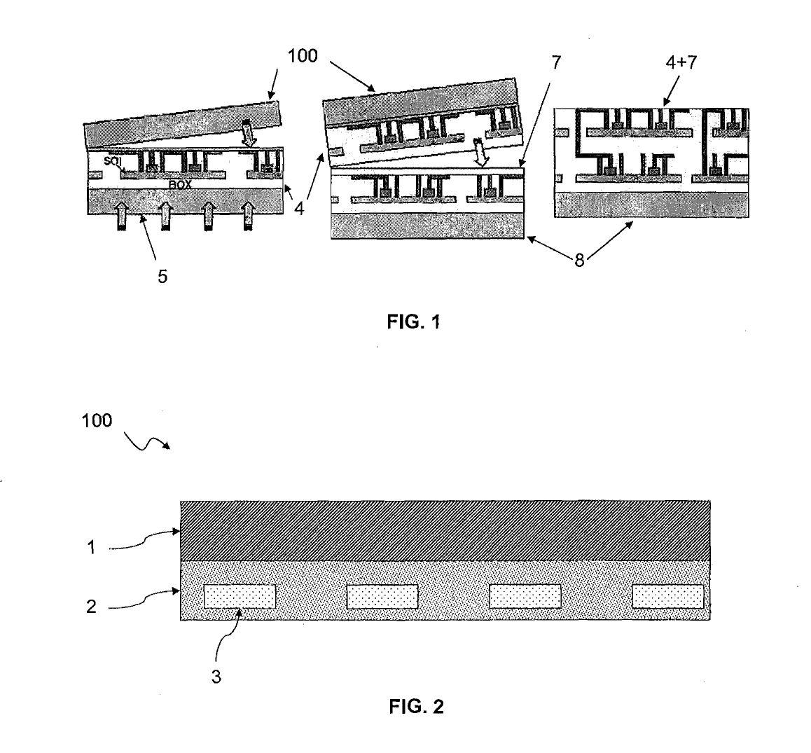

FIG. 2 shows a temporary substrate 100 according to a preferred embodiment of the present invention which comprises a surface layer 2, and inserts 3 arranged in this thin surface layer 2. The thickness of the surface layer 2 may vary by a few thousands of Å to a few μm.

The material or materials of the inserts 3 are different from the materials making up the rest of the surface layer 2, and are chosen so as to have different coefficients of thermal expansion. Typically, the material forming the inserts 3 should have a greater coefficient of expansion than the material of the layer 2.

Many couples of material may be envisaged, and in a particularly preferred embodiment, tetraethoxysilane (TEOS) oxide or silane is used for the surface layer 2 and copper is used for the inserts 3. A material such as copper has a high thermal conductivity, a tendency to expand and good ductility. Copper has a coefficient of linear expansion α, that corresponds, assuming the material to be anisotropic, to the elongation factor of a part for an increase of 1° K, of 16.5×10⁻⁶, compared with the value of 0.6×10⁻⁶ for silicon oxide or about 2.4 times. For different materials, a difference in coefficients of about 1.5 to 4 times is advantageous. Copper is preferred because it is easily electrodeposited. Metal compounds are generally preferably chosen for the inserts 3, but other types of materials having different coefficients of thermal expansion may be envisaged, such as Al₂O₃.

Advantageously, the surface layer 2 covers a principal part of the substrate 1, where the substrate ensures the rigidity of this support on account of its much greater thickness than that of the surface layer 2. This principal part of the substrate 1 may consist of all the materials normally used in substrates, notably based on silicon (e.g., Si, SiC, SiGe), glass, ceramic or a metal alloy. The choice of material could be made according to the constitution of the layer 4 to be transferred, as assessed or routinely determined by a person of ordinary skill in the art.

Preferred geometries for the arrangement of the inserts 3 in the surface layer 2 are described subsequently, it being possible for the inserts 3 to cover or be distributed over, for example, the entire surface of the temporary substrate 100.

A temporary substrate has the function of receiving, in a transient manner, an active layer (comprising circuits for example) with a view to bringing it to a final substrate.

The invention thus relates, according to a second aspect, to a method for transferring a thin layer 4 from an original substrate 5 to a final substrate 8 via a temporary substrate 100 such as previously described.

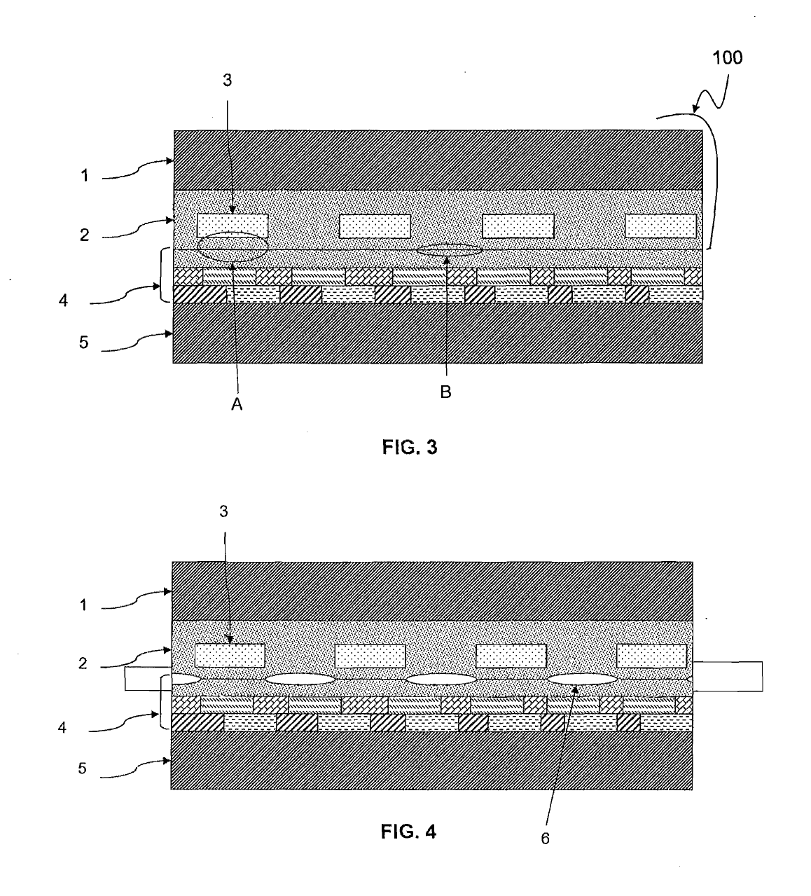

FIG. 3 shows the substrate 100 is first of all attached to one of the layer or layers 4 of a layered structure, before being transferred. This layered structure assembly will subsequently be referred to generically as a single layer. The presence of the substrate 100 is in fact made necessary since it is necessary to turn the layer 4 over. Any type of attachment may be employed, preferably of a molecular nature, notably an oxide-oxide hydrophilic attachment, in particular in the case of the use of a TEOS oxide for the surface layer 2.

Various types of interfaces between the substrate 100 and the layer 4 are also present. At the level of zones A vertically above an insert 3, there is only a very small distance between the insert 3 and the interface. On the other hand, at the level of zones B, the substrate is only made of material of the surface layer 2 over all its thickness.

A heat treatment is then performed for assembling the substrates. This heat treatment preferably takes the form of annealing with a temperature ramp of several hundreds of degrees Celsius. For example, in the case of a layer 2 made of silicon oxide (SiO₂) and copper inserts 3, the temperature to be reached during heat treatment will preferably lie between 350 and 400 degrees Celsius, preferably for at least two hours. This treatment brings about the expansion of the assembly, in particular the inserts 3, which will experience a substantial increase in thickness relative to that of the rest of the surface layer 2. This increase in thickness of the inserts will cause a greater increase in thickness of the combined inserts 3 and surface layer 2, compared to the regions of the surface layer 2 lacking the inserts 3. At the level of the zones A, the thermal expansion of the inserts 3 pushes the substrate 1 away from layer 4, and thus induces detachment at the level of the zones B, as shown in FIG. 3, and the creation of detachment zones or cavities 6 that may be seen in FIG. 4. These cavities 6 will be larger the lower the attachment energy at ambient temperature. A small distance from the surface of the insert 3 to the attachment interface will also facilitate detachment. Advantageously, this distance, which corresponds to thickness of the material of the surface layer 2 covering the inserts, is less than 5000 Å.

The substrate 5 is then removed, generally by chemical or mechanical means. It would be possible to envisage the removal of the substrate 5 before annealing, bringing about the appearance of cavities, that is to say to transpose the last two steps, on condition however that the stresses exerted on the structure (chemical or mechanical) do not bring about premature detachment from the substrate 1. It is however possible to apportion sufficiently the attachment used for fixing the temporary substrate 100 so that premature detachment is not caused even when the stresses applied are very high.

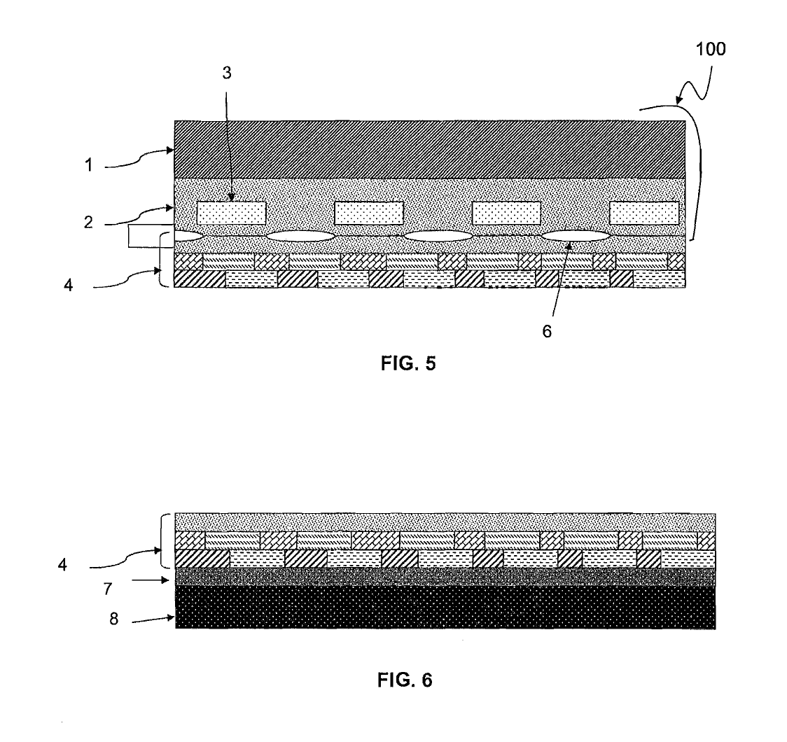

The structure obtained, shown in FIG. 5, is then attached to the final substrate 8, covered as the case may be with one or more layers 7 such as an oxide layer, and the temporary substrate 100 is withdrawn by a mechanical demounting action at the level of the weakened attachment interface so as to arrive at the final structure that may be seen in FIG. 6. In point of fact, after the heat treatment step, a consequent part of the interface between the temporary substrate 100 and the layer 4 is already detached at the cavities 6. Only a fraction of the force to be employed for normal detachment of a conventional temporary substrate is therefore necessary. By adjusting the geometry and pattern of the inserts 3, it is possible to control this fraction and also to make adhesion as secure as is desired between the temporary substrate 100 and the layer 4 before annealing and to make the final demounting as easy as is desired. This structure makes it possible to have two different levels of attachment and to pass from the first to the second by heat treatment.

Advantageously, the inserts 3 are distributed in the surface layer 2 in a regular pattern, in particular in a checkered pattern, with the inserts 3 having a square section. The invention is not however in any way limited to this geometry and may take many other forms such as a triangular layout.

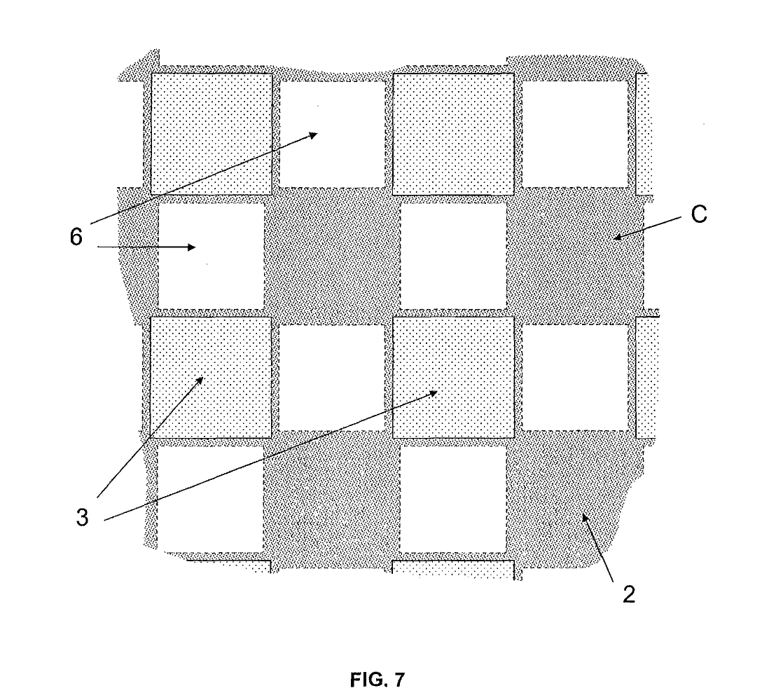

In the case of a chequered (checkered) pattern, it is particularly preferred to separate inserts two-by-two by a distance equivalent to their width, this distance being normally between 250 and 500 μm. The advantages of such geometry will become clearly apparent in FIG. 7. Zones that maintain attachment correspond to zones under the insert 3, and to the zones C that are at the intersection of two bands of unaffected materials of the layer 2, which are then not directly placed between two inserts. The detachment zones 6 cover the rest of the substrate 100. By virtue of the preferred geometry shown, it will be seen that the surfaces of the two zones are equal overall, annealing dividing the adhesion overall by a factor of two.

In such a configuration, considering that the coefficient of expansion of silicon oxide is 0.6×10⁻⁶ and that of copper is 16.5×10⁻⁶, that the latter is sufficiently ductile so that all expansion occurs in direction of the attachment interface, and that the thickness of the inserts is 1 μm, detachment greater than 100 Å is obtained, for annealing at 400 degrees Celsius, corresponding to the height of the cavities 6.

The invention finally relates, according to a third aspect, to a method for producing a temporary substrate 100 such as previously described.

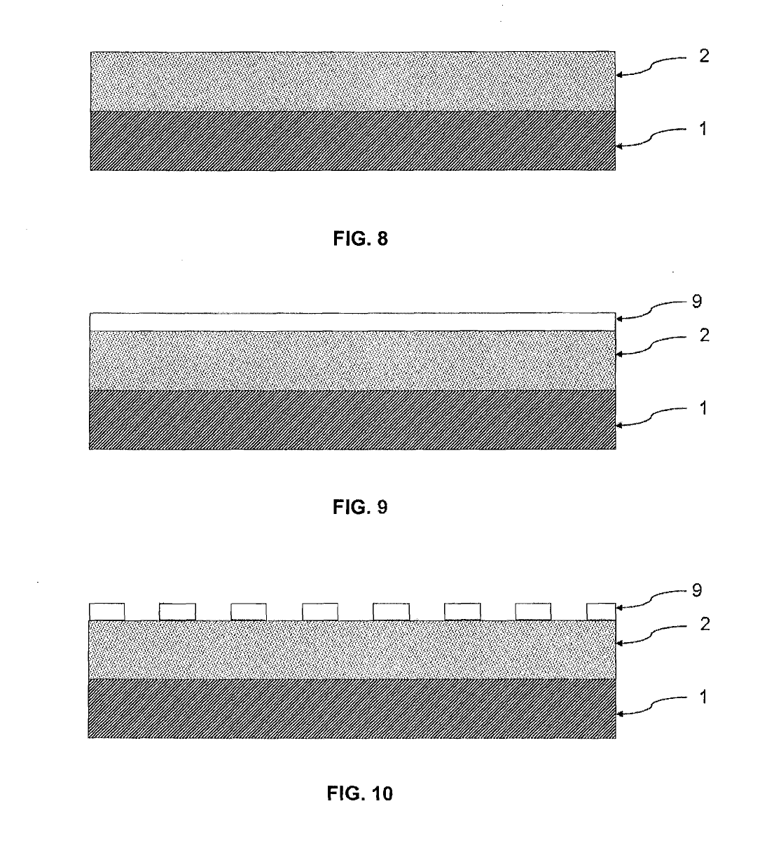

The production method, starting from the main bare part 1, commences by a step of depositing the surface layer 2, which may advantageously be carried out by PECVD if the material is a TEOS oxide or silane, to form a silicon oxide layer. PECVD, meaning plasma-enhanced chemical vapor deposition, is a known method for depositing a thin layer on a substrate from a gaseous state and makes it possible to obtain small thicknesses equal to or even less than a micron that are necessary for the invention. The temporary substrate 100 being produced is then in the state shown in FIG. 8.

The surface layer 2 is then etched to form cavities 10 that will contain or shelter the inserts 3. Photolithography may be used for this purpose. A photosensitive resin 9 that may be seen in FIG. 9 is deposited and exposed to radiation behind a mask that represents the negative of patterns to be etched (here, the zones that will receive the inserts 3), which is called insulation. The resin is developed, bringing about solution of the exposed parts (FIG. 10). The parts that are not to be etched are then protected by the resin, in comparison to the parts to be etched.

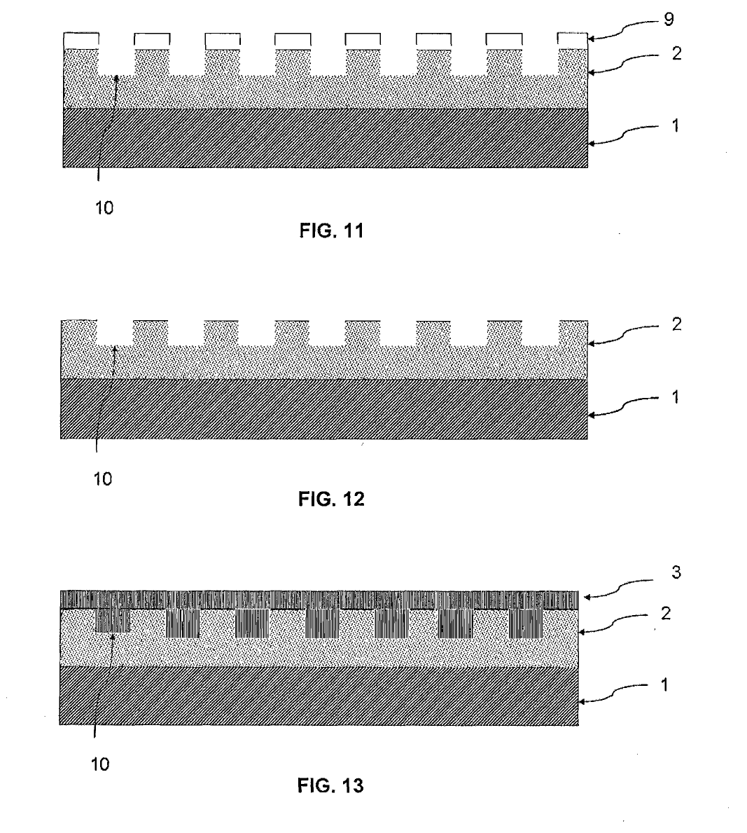

Various etching techniques, whether by a dry method (plasma) or a wet method (chemical attack, for example by hydrofluoric acid), are known to a person skilled in the art. Once the cavities 10 have been etched (FIG. 11), the rest of the photosensitive resin 9 is removed as appropriate. The substrate then has the surface state that may be seen in FIG. 12.

The cavities 10 are then filled with the material constituting the inserts 3. If this is copper, it is quite simply electrodeposited by electrolysis on the surface and filled a little more than the cavities 10 (see FIG. 13).

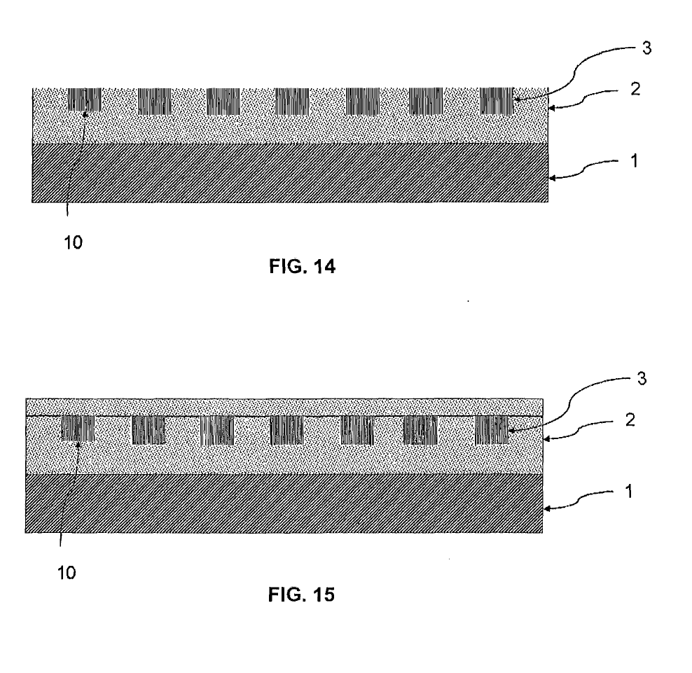

The excess material of the inserts 3 is then removed by mechano-chemical polishing until the material of the surface layer 2 is revealed. All that remains is to cover the inserts 3 at present in place in the cavities, as may be seen in FIG. 14. To this end, a thin layer of the material of the surface layer 2 is deposited so as to cover the inserts 3, this being once again carried out by PECVD (for TEOS or silane to form silicon oxide). Finally, the surface obtained after deposition (FIG. 15) is flattened by known methods (such as mechano-chemical polishing), as required so as to increase the ability of the surface to be attached against a layer 4 to be transferred.

What is claimed is:

1. A temporary substrate for the transfer of a thin layer of an original substrate to a final substrate, comprising:
a principle part of a substrate;
a surface layer formed on the surface of the principle part;
a plurality of inserts formed within the surface layer,
wherein the inserts have a coefficient of thermal expansion that is different from that of the surface layer.

2. The temporary substrate according to claim 1, wherein the principle part of the substrate is chosen from at least one of the following materials: Si, SiC, SiGe, glass, a ceramic, or a metal alloy.

3. The temporary substrate according to claim 1, wherein the surface layer is formed from a material chosen from at least one of the following materials: tetraethoxysilane or silane.

4. The temporary substrate according to claim 1, wherein the inserts are copper.

5. The temporary substrate according to claim 1, wherein the inserts are distributed in the surface layer in a regular pattern.

6. The temporary substrate according to claim 1, wherein the inserts are distributed in a checkered pattern.

7. The temporary substrate according to claim 6, wherein the inserts are separated two by two by a distance equivalent to their width.

8. The temporary substrate according to claim 7, wherein the width of the inserts or their spacing or both their width and spacing is a distance of between 250 and 500 μm.

9. The temporary substrate according claim 1, wherein the thickness of the surface layer is equal to or less than 1 μm.

10. The temporary substrate according claim 1, wherein the inserts are present within the surface layer and are covered by a thickness of material of the surface layer that is less than 5000 Å.

11. The temporary substrate according claim 1, wherein the inserts are placed within cavities in the surface layer.

12. The temporary substrate according claim 11, wherein the inserts are covered by subsequently applied additional amounts of surface layer.

13. A method for transferring a thin layer of an original substrate to a final substrate using a temporary substrate, comprising:
providing a temporary substrate according claim 1;
providing an original substrate having a thin layer;
attaching the upper face of the thin layer of the original substrate to the surface layer of the temporary substrate;
heat treating the original substrate, thin layer and temporary substrate to bring about the formation of detachment zones in the surface layer between the upper face of the thin layer and the temporary substrate.

14. The method according to claim 13, which further comprises:
eliminating the original substrate to reveal a lower face of the thin layer;
attaching the lower face of the thin layer to a final substrate; and
detaching by mechanical action the detachment zones of the surface of the temporary substrate that are still attached to the upper face of the thin layer.

15. A method for producing a temporary substrate according to claim 1, comprising:
providing a substrate having a principle part at a surface;
depositing an initial surface layer on the principal part of the substrate;
etching the surface layer to form cavities therein;
depositing a layer of a material on the surface layer so as to fill the cavities;
polishing the layer of the material deposited on the surface layer until the initial surface layer is revealed to form a plurality of inserts; and
depositing a thin layer of material forming the surface layer on the revealed surface layer and filled cavities, so as to cover the inserts.

16. The method according to claim 15, wherein the material of the surface layer is deposited by plasma-enhanced chemical vapor deposition (PECVD).

17. The method according to claim 15, wherein the polishing is a mechano-chemical polishing.

18. The method according to claim 15, wherein the material deposited on the surface layer to fill the cavities is copper.

19. The method according to claim 15, which further comprises polishing the thin layer of material deposited to cover the inserts to flatten the deposited surface.
